(19) United States
(12) Patent Application Publication
(10) Pub. No.: US 2026/0313884 A1
(43) Pub. Date: Oct. 8, 2026

(54) GATE EXTENSION TO TUNE THRESHOLD VOLTAGE

(71) Applicant: Micron Technology, Inc., Boise, ID (US)

(72) Inventors: Martin Brox, Muenchen (DE); Jan Pottgiesser, Unterhaching (DE); Andreas Kuesel, Muenchen (DE)

(21) Appl. No.: 19/170,472

(22) Filed: Apr. 4, 2025

(51) Int. Cl. H10B 12/00

(52) U.S. Cl. CPC H10B 12/50

(57) ABSTRACT

A variety of applications can include one or more integrated circuits having metal oxide semiconductor field effect transistors with gate extensions extending from the gates of the transistors to outside source/drain diffusion regions to tune threshold voltages of the transistors without a unique implant layer. An integrated circuit can comprise a set of complementary metal oxide semiconductor (CMOS) devices, where the set includes two CMOS devices having transistors with low threshold voltages and a third CMOS device having transistors with high threshold voltages. The third CMOS device can be positioned between and adjacent the two CMOS devices and the transistors of the third CMOS device can have gate extensions that extend from gates of the transistors beyond source and drain diffusion regions of the transistors of the third CMOS device such that the high threshold voltages are shifted above the low threshold voltages due to the gate extensions.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design or fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a top view of a portion of an integrated circuit having a layout of a mix of complementary metal oxide semiconductor devices from a first family and complementary metal oxide semiconductor devices from a second family, in accordance with various embodiments.

FIG. 2 illustrates a top view of an arrangement of two complementary metal oxide semiconductor devices having a layout that is considered a good complementary metal oxide semiconductor cell layout, in accordance with various embodiments.

FIG. 3 illustrates a top view of an arrangement of a complementary metal oxide semiconductor devices having a layout that is considered a bad complementary metal oxide semiconductor cell layout, due to the extended gate stacks of the transistors of complementary metal oxide semiconductor devices, in accordance with various embodiments.

FIG. 4 illustrates a top view of a portion of an integrated circuit with a layout having a mix of complementary metal oxide semiconductor devices from a first family and a complementary metal oxide semiconductor device from a second family, in accordance with various embodiments.

FIG. 5 is a cross-sectional view of an arrangement along a line of the integrated circuit of FIG. 4, in accordance with various embodiments.

FIG. 6 is a flow diagram of features of an example method of forming an integrated circuit, in accordance with various embodiments.

FIG. 7 is a schematic of an example dynamic random-access memory that can include an architecture in which multiple complementary metal oxide semiconductor devices in the periphery to the memory array of the dynamic random-access memory device are structured with a layout having a mix of complementary metal oxide semiconductor devices from a first family and a complementary metal oxide semiconductor device from a second family, in accordance with various embodiments.

FIG. 8 is a block diagram of an example machine in which one or more integrated circuits have multiple complementary metal oxide semiconductor devices structured with a layout having a mix of complementary metal oxide semiconductor devices from a first family and a complementary metal oxide semiconductor device from a second family, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The various embodiments are not necessarily mutually exclusive, as some embodiments can be combined with one or more other embodiments to form new embodiments. The following detailed description is, therefore, not to be taken in a limiting sense.

Different transistor types are used to optimize leakage versus performance in complementary metal oxide semiconductor (CMOS) technologies. A CMOS device has a p-type metal oxide semiconductor field effect transistors (MOSFET), which can be referred to as a PMOS transistor, and a n-type MOSFET, which can be referred to as a NMOS transistor. The gate of the PMOS transistor is connected to the gate of the NMOS transistor by a conductive element. The drain of the PMOS transistor is connected to the drain of the NMOS transistor, while sources of the PMOS transistor and the NMOS transistor are connected to their usual power rails. To simplify the following description, connections to source and drain are not shown in the Figures. With the source and drain of a MOS transistor having similar structures, the source and drain can be referred to source/drains.

In various applications, a significant number of CMOS devices can be structured in an IC arranged as at least two families of CMOS devices. A first family can include CMOS devices in which the PMOS transistors and the NMOS transistors have low voltage thresholds (Vths). A second family can include CMOS devices in which the PMOS transistors and the NMOS transistors have high voltage thresholds (Vths). Low Vths and high Vths can be defined by the application in which transistors are implemented. For example, in a periphery to an array of memory cells in a memory die such as, but not limited to, a DRAM die, a low Vth of the transistors of CMOS devices can have a value of 0.2 volts and a high Vth of the transistors of CMOS devices can have a value of 0.5 volts. In such memory devices, low Vth transistors can have Vths less than 0.3V and high Vth transistors can have Vths greater than 0.4V.

MOSFETs having a low Vth offer high performance at the price of high current leakage, at least higher current leakage than for a high Vth. MOSFETs having a high Vth offer low current leakage, at least lower current leakage than for a low Vth, at the price of low performance. High performance transistors are typically used for critical, high-speed circuitry, where high speed refers to a clock period less than, for example, 1 ns. Low performance transistors are typically used for low-speed support functions, where low-speed refers to a clock period greater than, for example, 4 ns. A high-performance transistor can differ from a low-performance transistor by implants that adjust the Vths of the two types of transistors. The adjustment of the Vths of the two types of transistors during fabrication by implanting different levels of dopants provides a mechanism to tune the Vths for the transistors. For applications in which MOSFETs are to be structured consuming a minimal amount of area of a die, such as in memory dies, low-Vth and high-Vth MOSFETs cannot be freely mixed. Vth-implants are employed to meet minimum area rules, where the minimum area rules set the minimum area of each implant region, which is typically much larger than the area of a single device. Therefore, if a circuit needs in general to operate at high speed, but still has some support logic which only needs to operate at low speed, these low-speed circuits can often not use the low speed library. The layout area of the circuitry might be too small and would violate the minimum are rules. As a consequence, not being able to mix transistor types can lead to leakage current that is higher than desired in an unlimited mix of transistors.

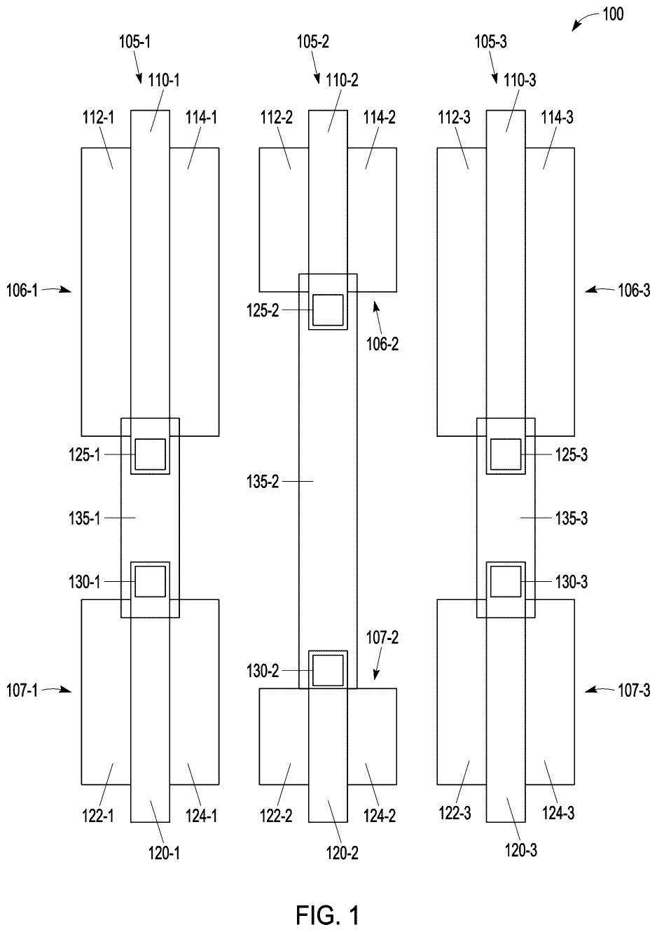

FIG. 1 illustrates a top view of a portion of an IC 100 having a layout of a mix of CMOS devices from the first family and CMOS devices from the second family. Two CMOS devices 105-1 and 105-3 are in the first family having transistors with low threshold voltages and a CMOS device 105-2 is in the second family having transistors with high threshold voltages. Though three CMOS devices are shown, the three CMOS devices can be in a set of CMOS devices in IC 100 that includes significantly more than three CMOS devices, where each CMOS device of the set is directly adjacent another CMOS of the set.

CMOS device 105-1 can include a PMOS transistor 106-1 having source/drain diffusion regions 112-1 and 114-1 and a gate stack 110-1, with gate stack 110-1 coupled to a contact 125-1. CMOS device 105-1 also includes a NMOS transistor 107-1 having source/drain diffusion regions 122-1 and 124-1 and a gate stack 120-1, with gate stack 120-1 coupled to a contact 130-1. Contact 125-1 is connected to contact 130-1 by connector 135-1. Connector 135-1 can be a metal or other low resistance material.

CMOS device 105-2 can include a PMOS transistor 106-2 having source/drain diffusion regions 112-2 and 114-2 and a gate stack 110-2, with gate stack 110-2 coupled to a contact 125-2. CMOS device 105-2 also includes a NMOS transistor 107-2 having source/drain diffusion regions 122-2 and 124-2 and a gate stack 120-2, with gate stack 120-2 coupled to a contact 130-2. Contact 125-2 is connected to contact 130-2 by connector 135-2. Connector 135-2 can be a metal or other low resistance material.

CMOS device 105-3 can include a PMOS transistor 106-3 having source/drain diffusion regions 112-3 and 114-3 and a gate stack 110-3, with gate stack 110-3 coupled to a contact 125-3. CMOS device 105-3 also includes a NMOS transistor 107-3 having source/drain diffusion regions 122-3 and 124-3 and a gate stack 120-3, with gate stack 120-3 coupled to a contact 130-3. Contact 125-3 is connected to contact 130-3 by connector 135-3. Connector 135-3 can be a metal or other low resistance material.

For CMOS device 105-2 to be structured in the layout of IC 100 as CMOS device having a high threshold voltage, the distance between the source/drain diffusion regions of CMOS device 105-1 and CMOS device 105-2 and the distance between source/drain diffusion regions of CMOS device 105-3 and CMOS device 105-2 are greater than the minimum distance between adjacent active areas set by design rules. For ICs like memory devices, mixing families of CMOS devices in a layout of directly adjacent CMOS devices can consume an unwanted amount of additional area of the die, since area for Vth implants needs to meet the minimum area for each family independently. To attain appropriate density of CMOS devices, without consuming excess area, CMOS devices are conventionally grouped by families, without mixing CMOS devices.

Another factor that can affect layout of CMOS devices in ICs such as memory devices is the use of processes implementing high-k metal gates (HKMG) for the transistors of the CMOS. A HKMG is a gate comprising a metal located on and contacting a high-k dielectric, where a high-k dielectric is a dielectric having a dielectric constant greater than the dielectric constant of silicon dioxide. Optionally, a HKMG can include its high-k dielectric on and contacting a thin layer of silicon oxide (SiOₓ). The HKMG can be situated as part of a gate stack with polysilicon on and contacting the metal of the HKMG. The polysilicon can be doped sufficiently to be appropriately conductive. Optionally, the gate stack can include one or more metals on the polysilicon. HKMG processing reacts sensitively to layout of the components of the HKMG. To achieve a controlled low Vth, a layout follows tight rules for fabrication, which may be a mayor limitation in HKMG-CMOS layout.

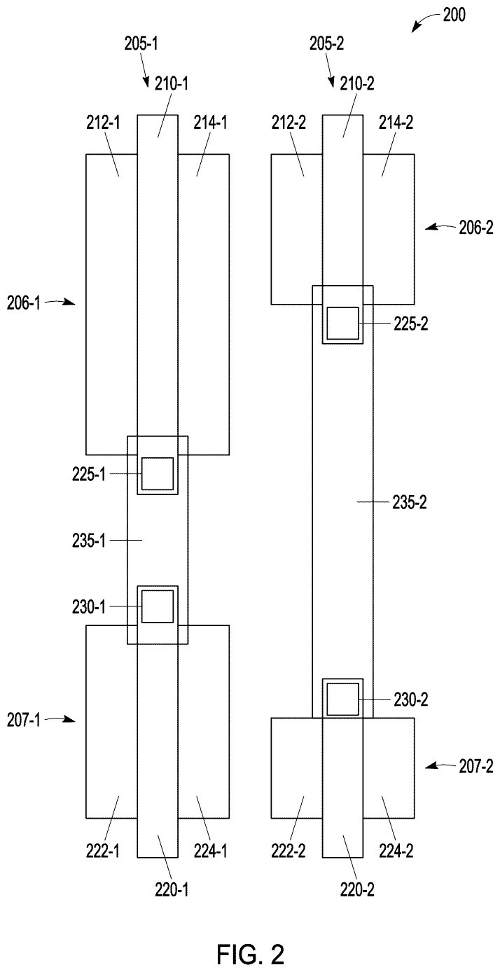

FIG. 2 illustrates an arrangement 200 of two CMOS devices 205-1 and 205-2 having a layout that is considered a good CMOS cell layout. CMOS device 205-1 can include a PMOS transistor 206-1 having source/drain diffusion regions 212-1 and 214-1 and a gate stack 210-1, with the gate stack 210-1 coupled to a contact 225-1. CMOS device 205-1 also includes a NMOS transistor 207-1 having source/drain diffusion regions 222-1 and 224-1 and a gate stack 220-1, with gate stack 220-1 coupled to a contact 230-1. Contact 225-1 is connected to contact 230-1 by connector 235-1. Connector 235-1 can be a metal or other low resistance material. Contact 225-1 is at the edges of source/drain diffusion regions 212-1 and 214-1 to make the gate to gate contact of PMOS transistor 206-1 as short as possible. Contact 230-1 is at the edges of source/drain diffusion regions 222-1 and 224-1 to make the gate to gate contact of NMOS transistor 207-1 as short as possible.

CMOS device 205-2 can include a PMOS transistor 206-2 having source/drain diffusion regions 212-2 and 214-2 and a gate stack 210-2, with gate stack 210-2 coupled to a contact 225-2. CMOS device 205-2 also includes a NMOS transistor 207-2 having source/drain diffusion regions 222-2 and 224-2 and a gate stack 220-2, with the gate stack 220-2 coupled to a contact 230-2. Contact 225-2 is connected to contact 230-2 by connector 235-2. Connector 235-2 can be a metal or other low resistance material. Contact 225-2 is at the edges of source/drain diffusion regions 212-2 and 214-2 to make the gate to gate contact of PMOS transistor 206-2 as short as possible. Contact 230-2 is at the edges of source/drain diffusion regions 222-2 and 224-2 to make the gate to gate contact of NMOS transistor 207-2 as short as possible.

Adjacent CMOS devices 205-1 and 205-2 in arrangement 200 are set apart from each other to satisfy minimum distance specifications. Both CMOS devices 205-1 and 205-2 have gate to gate contact having distances as short as possible such that gate stacks or a portion of gate stacks do not extend much past the edges of source/drain diffusion regions.

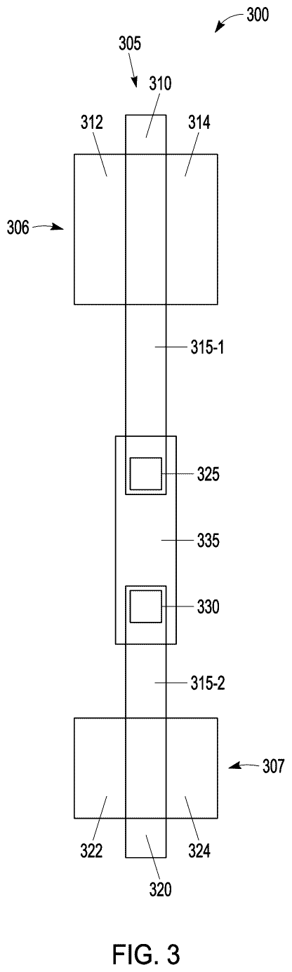

FIG. 3 illustrates an arrangement 300 of a CMOS devices 305 having a layout that is considered a bad CMOS cell layout, due to the extended gate stacks of the transistors of CMOS devices 305. CMOS device 305 can include a PMOS transistor 306 having source/drain diffusion regions 312 and 314 and a gate stack 310, with gate stack 310 coupled to a contact 325 by a gate extension 315-1 that extends from the edges of source/drain diffusion regions 312 and 314. Gate extension 315-1 is part of gate stack 310. CMOS device 305 also includes a NMOS transistor 307 having source/drain diffusion regions 322 and 324 and a gate stack 320, with gate stack 320 coupled to a contact 330 by a gate extension 315-2 that extends from the edges of source/drain diffusion regions 322 and 324. Gate extension 315-2 is part of gate stack 320. Contact 325 is connected to contact 330 by connector 335. Connector 335 can be a metal or other low resistance material. Extending gate stacks 310 and 320 or portions of gate stacks 310 and 320 outside the diffusion regions diffusion regions 312 and 314 and 322 and 324, respectively, of the transistors of CMOS device 305 can increase the Vth of PMOS transistor 306 and the Vth of NMOS transistor 307.

In various embodiments, a bad layout for a CMOS device can be used to mix families of CMOS devices in a layout of a set of CMOS devices. The Vth for a low performance CMOS device can be increased not by using a unique implant but by extending the gate stack with a gate extension. In this manner, several enhancements can be achieved. First, the tuning of the Vth can be attained without a unique implant layer to create high-Vth transistors without an additional mask. Secondly, high Vth transistors and low Vth transistors can be mixed without a minimum area limitation.

An IC can comprise a set of CMOS devices having at least two different families of CMOS devices in the set. Each CMOS device of the set can be directly adjacent another CMOS of the set. Each transistor of a first family of CMOS devices of the set can have a low threshold voltage. Each transistor of a second family of CMOS devices of the set can have a high threshold voltage. One or more CMOS devices of the second family can be mixed with CMOS devices of the first family such that transistors of the one or more CMOS devices of the second family have implant levels substantially equal to implant levels of the CMOS devices of the first family. The high threshold voltages of the transistors of the one or more CMOS devices can be based on gate extensions that extend from gates of the transistors of the one or more CMOS devices substantially beyond source and drain diffusion regions of the transistors of the one or more CMOS devices.

Variations of such an IC and its features, as taught herein, can include a number of different embodiments and features that may be combined depending on the application of such ICs, the format of such ICs, and/or the architecture in which such ICs are implemented. Features of such ICs can include the gate extensions structured with polysilicon. Variations can include the transistors of the first family and the second family having high-k metal gates.

Variations of such an IC and its features can include the IC being a memory device. The set of CMOS devices can be structured in a periphery to a memory array of the memory device, with the first family arranged to support high speed circuitry in the periphery and the second family arranged to provide low speed support functions. The memory device can be a DRAM.

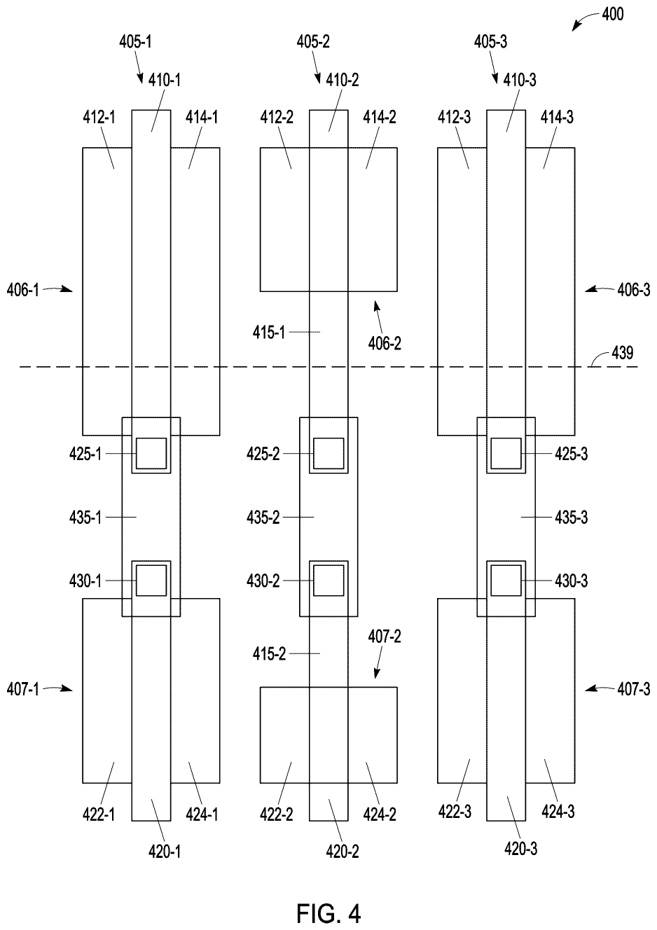

FIG. 4 illustrates a top view of a portion of an IC 400 with a layout having a mix of CMOS devices from a first family and a CMOS device from a second family for which high-Vth and low-Vth transistors are freely mixed without a minimum area limitation. Two CMOS devices 405-1 and 405-3 are in the first family having transistors with low threshold voltages and CMOS device 405-2 is in the second family having transistors with high threshold voltages. Though three CMOS devices are shown, the three CMOS devices can be in a set of CMOS devices in IC 100 that includes significantly more than three CMOS devices. Each CMOS device of the set can be directly adjacent another CMOS of the set.

CMOS device 405-1 can include a PMOS transistor 406-1 having source/drain diffusion regions 412-1 and 414-1 and a gate stack 410-1, with gate stack 410-1 coupled to a contact 425-1. CMOS device 405-1 also includes a NMOS transistor 407-1 having source/drain diffusion regions 422-1 and 424-1 and a gate stack 420-1, with gate stack 420-1 coupled to a contact 430-1. Contact 425-1 is connected to contact 430-1 by connector 435-1. Connector 435-1 can be a metal or other low resistance material.

CMOS device 405-2 can include a PMOS transistor 406-2 having source/drain diffusion regions 412-2 and 414-2 and a gate stack 410-2, with gate stack 410-2 coupled to a contact 425-2 by a gate extension 415-1 that extends from the edges of source/drain diffusion regions 412-2 and 414-2. CMOS device 405-2 also includes a NMOS transistor 407-2 having source/drain diffusion regions 422-2 and 424-2 and a gate stack 420-2, with gate stack 420-2 coupled to a contact 430-2 by a gate extension 415-2 that extends from the edges of source/drain diffusion regions 422-2 and 424-2. Contact 425-2 is connected to contact 430-2 by connector 435-2. Connector 435-2 can be a metal or other low resistance material. With CMOS device 405-2 having gate extensions 415-1 and 415-2, CMOS device 405-2 can be designed as a low-Vth CMOS with respect to implanting dopants for the transistors of CMOS device 405-2, with its Vth tuned to a high Vth via gate extensions 415-1 and 415-2. The length of gate extensions 415-1 and 415-2 to contacts 425-2 and 430-2 can be correlated to the amount of tuning to increase the Vth to the desired Vth from the designed low Vth.

CMOS device 405-3 can include a PMOS transistor 406-3 having source/drain diffusion regions 412-3 and 414-3 and a gate stack 410-3, with gate stack 410-3 coupled to a contact 425-3. CMOS device 405-3 also includes a NMOS transistor 407-3 having source/drain diffusion regions 422-3 and 424-3 and a gate stack 420-3, with gate stack 420-3 coupled to a contact 430-3. Contact 425-3 is connected to contact 430-3 by connector 435-3. Connector 435-4 can be a metal or other low resistance material.

NMOS transistors 407-1, 407-2, and 407-3 can have a common implant level. PMOS transistors 406-1, 406-2, and 406-3 can have a common implant level. The gate stacks of CMOS devices 405-1, 405-2, and 4-5-3 can have a similar structure. These gate stacks can include HKMGs. The gate stacks can include polysilicon on and contacting the metal gate of the HKMG. Gate extensions 415-1 and 415-2 can be continuous extensions from the top conductive portion of gate stacks 410-2 and 420-2, respectively, either as a single layer of the respective gate stack or multiple layers of the gate stack. Polysilicon can be part of gate extensions 415-1 and 415-2.

While contact 430-2 to the gate of NMOS transistor 407-2 is located substantially at an end of gate extension 415-2, opposite edges of the source/drain diffusion regions 422-2 and 424-2 of NMOS transistor 407-2 of CMOS device 405-2, contact 430-1 to the gate of NMOS transistor 407-1 is located substantially at edges of source/drain diffusion regions 422-1 and 424-1 of NMOS transistor 407-1 and contact 430-3 to the gate of NMOS transistor 407-3 is located substantially at edges of source/drain diffusion regions 422-3 and 424-3 of NMOS transistor 407-1. While contact 425-2 to the gate of PMOS transistor 406-2 is located substantially at an end of gate extension 415-1, opposite edges of the source/drain diffusion regions 412-2 and 414-2 of PMOS transistor 406-2 of CMOS device 405-2, contact 425-1 to the gate of PMOS transistor 406-1 is located substantially at edges of source/drain diffusion regions 412-1 and 414-1 of PMOS transistor 406-1 and contact 425-3 to the gate of PMOS transistor 406-3 is located substantially at edges of source/drain diffusion regions 412-3 and 414-3 of PMOS transistor 406-1. Contacts 430-1, 430-2, and 430-3 can be colinear. Contacts 425-1, 425-2, and 425-3 can be colinear.

IC 400 can be a memory device. IC 400 can be a DRAM. The set of CMOS devices can be structured in a periphery to a memory array of the DRAM. In some memory devices, the set of CMOS devices can be structured in a periphery to a memory array that is under the memory array of the given memory devices.

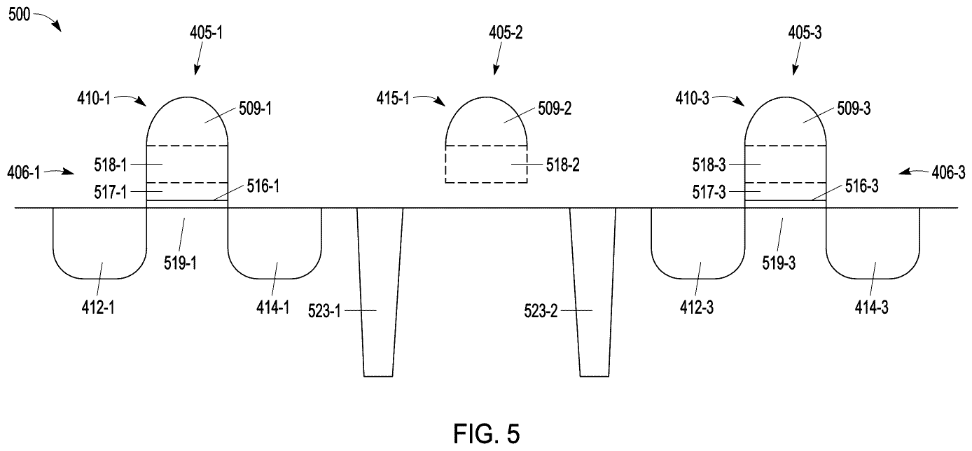

FIG. 5 illustrates a cross-sectional view of an arrangement 500 along line 439 of IC 400 of FIG. 4. Arrangement 500 shows CMOS device 405-1 separated from CMOS device 405-2 by a shallow trench insulator (STI) 523-1 and CMOS device 405-2 separated from CMOS device 405-3 by STI 523-2. Gate stack 410-1 of PMOS transistor 406-1 of CMOS device 405-1 is situated on channel structure 519-1 that couples source/drain diffusion region 412-1 to source/drain diffusion region 414-1. Gate stack 410-1 can be structured as polysilicon 509-1 on and contacting a metal gate 518-1 that is on and contacting a high-k dielectric 517-1, which can be on and contacting a thin silicon oxide 516-1. Metal gate 518-1, high-k dielectric 517-1, and silicon oxide 516-1 form a HKMG.

Along line 439, CMOS device 405-2 does not include the source/drain diffusion regions 412-2 and 414-2 of PMOS transistor 406-2 of CMOS device 405-2, but includes extension 415-1 that connects gate stack 410-2 of PMOS transistor 406-2 to contact 425-2 shown in FIG. 4. Extension 415-1 can include polysilicon 509-2 having conductive properties to connect gate stack 410-2 to contact 425-2. Alternatively, extension 415-1 can include polysilicon 509-2 on and contacting a metal gate 518-2 from gate stack 410-2 extending to connect gate stack 410-2 to contact 425-2.

Gate stack 410-3 of PMOS transistor 406-3 of CMOS device 405-3 is situated on channel structure 519-3 that couples source/drain diffusion regions 412-3 to source/drain diffusion regions 414-3. Gate stack 410-3 can be structured as polysilicon 509-3 on and contacting a metal gate 518-3 that is on and contacting a high-k dielectric 517-3, which can be on and contacting a thin silicon oxide 516-3. Metal gate 518-3, high-k dielectric 517-3, and silicon oxide 516-3 form a HKMG.

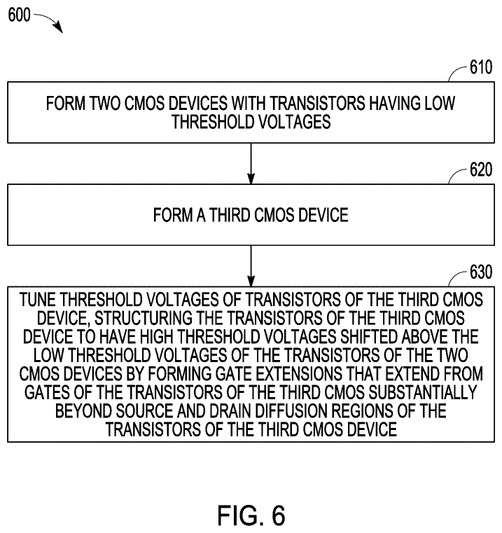

FIG. 6 is a flow diagram of features of an embodiment of an example method 600 of forming an IC. At 610, two CMOS devices are formed with transistors having low threshold voltages. At 620, a third CMOS device is formed. The third CMOS can be formed structured between and directly adjacent the two CMOS devices. The two CMOS devices and the third CMOS device can be formed in an integrated process.

At 630, threshold voltages of transistors of the third CMOS device are tuned, structuring the transistors of the third CMOS device to have high threshold voltages shifted above the low threshold voltages of the transistors of the two CMOS. The tuning is achieved by forming gate extensions that extend from gates of the transistors of the third CMOS device substantially beyond source and drain diffusion regions of the transistors of the third CMOS device.

Variations of method 600 or methods similar to method 600 can include a number of different embodiments that may be combined depending on the application of such methods or the architecture or operation flow for which such methods are implemented. Such methods can include forming n-type transistors of the two CMOS devices and the third CMOS device having a common implant level, and forming p-type transistors of the two CMOS devices and the third CMOS device having a common implant level.

Variations of method 600 or methods similar to method 600 can include forming contacts to gates of the two CMOS devices and the third CMOS device, where contacts to the gates of the n-type transistors of the two CMOS devices can be formed substantially at edges of source and drain diffusion regions of the n-type transistors of the two CMOS devices. A contact to the gate of the n-type transistor of the third CMOS device can be formed substantially at an end of the gate extension associated with the third CMOS device, opposite edges of the source and drain diffusion regions of the n-type transistor of the third CMOS device. Contacts to the gates of the p-type transistors of the two CMOS devices can be formed substantially at edges of source and drain diffusion regions of the p-type transistors. Contact to the gate of the p-type transistor of the third CMOS device can be formed substantially at an end of the gate extension associated with the third CMOS device, opposite edges of the source and drain diffusion regions of the p-type transistor of the third CMOS device. Variations can include forming the contacts to the gates of the n-type transistors of the two CMOS devices colinear with the contact to the gate of the n-type transistor of the third CMOS device, and forming the contacts to the gates of the p-type transistors of the two CMOS devices colinear with the contact to the gate of the p-type transistor of the third CMOS device.

Variations of method 600 or methods similar to method 600 can include forming high-k metal gates in the formation of the transistors of the two CMOS devices and the third CMOS device. Forming gate extensions includes forming polysilicon as at least part of the gate extensions.

Variations of method 600 or methods similar to method 600 can include forming the integrated circuit as a memory die and forming a set of CMOS devices structured in a periphery to a memory array of the memory die. The set of CMOS devices can be structured as a first family of CMOS devices and a second family of CMOS devices. Each transistor of the first family can have a low threshold voltage and each transistor of the second family can have a high threshold voltage.

In various embodiments, an IC can include a set of complementary metal oxide semiconductor (CMOS) devices, where the set includes two CMOS devices having transistors with low threshold voltages and a third CMOS device having transistors with high threshold voltages. The third CMOS device can be structured between and adjacent the two CMOS devices. The transistors of the third CMOS device can have gate extensions that extend from gates of the transistors beyond source/drain diffusion regions of the transistors of the third CMOS device such that the high threshold voltages are shifted above the low threshold voltages due to the gate extensions. The n-type transistors of the two CMOS devices and the n-type transistor of the third CMOS device can have a common implant level and the p-type transistors of the two CMOS devices and the p-type transistor of the third CMOS device have a common implant level.

In such an IC, contacts to gates of n-type transistors of the two CMOS devices can be located substantially at edges of source and drain diffusion regions of the n-type transistors of the two CMOS devices. A contact to the gate of the n-type transistor of the third CMOS device can be located substantially at an end of the gate extension, opposite edges of the source/drain diffusion regions of the n-type transistor of the third CMOS device.

In such an IC, contacts to gates of p-type transistors of the two CMOS devices can be located substantially at edges of source and drain diffusion regions of the p-type transistors and the contact to the gate of a p-type transistor of the third CMOS device can be located substantially at an end of the gate extension opposite edges of the source/drain diffusion regions of the p-type transistor of the third CMOS device.

In such an IC, contacts to gates of the n-type transistors of the two CMOS devices and the contact to the gate of the n-type transistor of the third CMOS device can be colinear. Contacts to the gates of the p-type transistors of the two CMOS devices and the contact to the gate of the p-type transistor of the third CMOS device can be colinear.

In such an IC, the gates of the transistors of the two CMOS devices and the gates of the transistors of the third CMOS can include high-k metal gates. The gates of the transistors of the third CMOS ca include polysilicon that is part of the gate extensions.

The IC can be a DRAM. The set of CMOS devices of the IC can be structured in a periphery to a memory array of the DRAM.

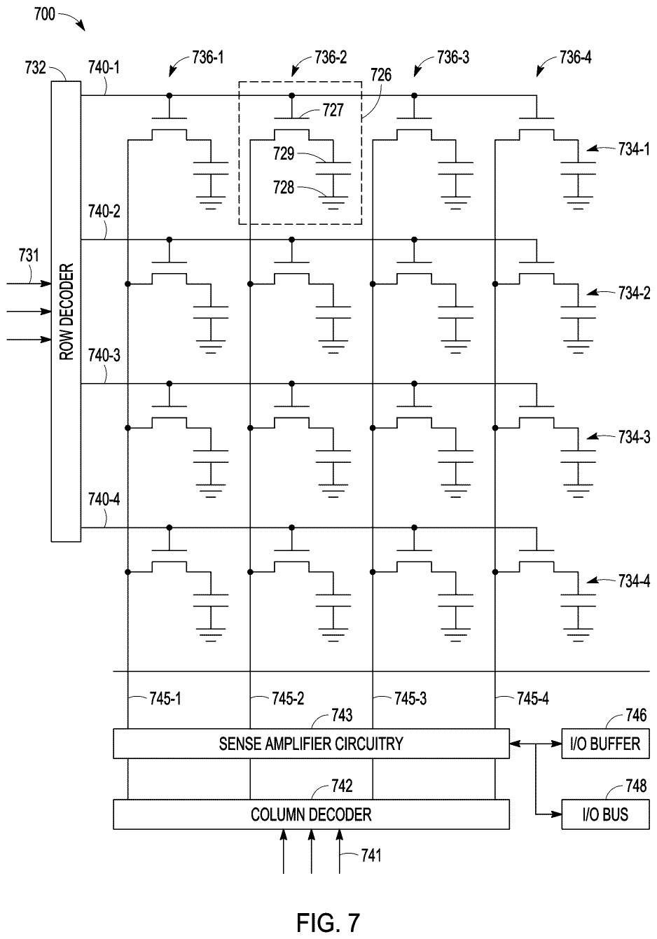

FIG. 7 is a schematic of an embodiment of an example DRAM 700 that can include an architecture in which transistors in the periphery to the memory array of DRAM 700 are structured with gate extensions extending from the gates of the transistors to outside source/drain diffusion regions of the transistors to tune threshold voltages of the transistors without a unique implant layer, as taught herein. DRAM 700 can include an array of memory cells 726 (only one being labeled in FIG. 7 for ease of presentation) arranged in rows 734-1, 734-2, 734-3, and 734-4 and columns 736-1, 736-2, 736-3, and 736-4. For simplicity and ease of discussion, the array is shown in only two dimensions, but the array can be extended into the third dimension. Further, while only four rows 734-1, 734-2, 734-3, and 734-4 and four columns 736-1, 736-2, 736-3, and 736-4 of four memory cells are illustrated, DRAMs like DRAM 700 can have significantly more memory cells 726 (e.g., tens, hundreds, or thousands of memory cells) per row or per column.

Each memory cell 726 can include a single transistor 727 and a single capacitor 729, which is commonly referred to as a 1T1C (one-transistor-one capacitor cell). One plate of capacitor 729, which can be termed the “node plate,” is connected to the drain terminal of transistor 727, whereas the other plate of the capacitor 729 is connected to a reference 728, which can be ground. Each capacitor 729 within the array of 1T1C memory cells 726 typically serves to store one bit of data, and the respective transistor 727 serves as an access device to write to or read from storage capacitor 729.

The transistor gate terminals within each row of rows 734-1, 734-2, 734-3, and 734-4 are portions of respective access lines (WLs) 740-1, 740-2, 740-3, and 740-4 (for example, word lines), and the transistor source terminals within each of columns 736-1, 736-2, 736-3, and 736-4 are electrically connected to respective digit lines (DLs) 745-1, 745-2, 745-3, and 745-4 (for example bit lines). A row decoder 732 can selectively drive the individual WLs 740-1, 740-2, 740-3, and 740-4, responsive to row address signals 731 input to row decoder 732. Transistors within row decoder 732 can be structured as taught herein. Driving a given WL at a high voltage causes the access transistors within the respective row to conduct, thereby connecting the storage capacitors within the row to the respective DLs, such that charge can be transferred between the DLs and the storage capacitors for read or write operations. Both read and write operations can be performed via sense amplifier circuitry 743, which can transfer bit values between the memory cells 726 of the selected row of the rows 734-1, 734-2, 734-3, and 734-4 and input/output buffers 746 (for write/read operations) or external input/output data buses 748. Transistors within sense amplifier circuitry 743 can be structured as taught herein.

A column decoder 742 responsive to column address signals 741 can select which of the memory cells 726 within the selected row is read out or written to. Transistors within column decoder 742 can be structured as taught herein. Alternatively, for read operations, the storage capacitors 729 within the selected row may be read out simultaneously and latched, and the column decoder 742 can then select which latch bits to connect to the output data bus 748. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM 700 may be implemented as an integrated circuit within a package that includes pins for receiving supply voltages (e.g., to provide the source and gate voltages for the transistors 727) and signals (including data, address, and control signals). FIG. 7 depicts DRAM 700 in simplified form to illustrate basic structural components, omitting many details of the memory cells 726 and associated WLs 740-1, 740-2, 740-3, and 740-4 and DLs 745-1, 745-2, 745-3, and 745-4 as well as the peripheral circuitry. For example, in addition to row decoder 732 and column decoder 742, sense amplifier circuitry 743, and buffers 746, DRAM 700 may include further peripheral circuitry, such as a memory control unit that controls the memory operations based on control signals (provided, e.g., by an external processor), additional input/output circuitry, etc. Transistors within the peripheral circuitry can be structured as taught herein. Details of such peripheral circuitry are generally known to those of ordinary skill in the art and not further discussed herein.

Many electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

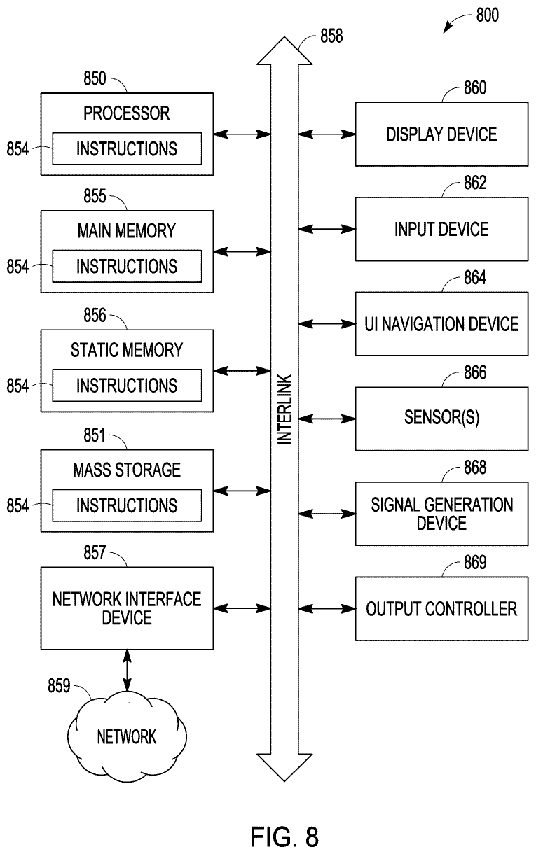

FIG. 8 illustrates a block diagram of an example machine 800 having one or more embodiments of transistors as discussed herein, for example in memory devices incorporated in machine 800. In alternative embodiments, machine 800 may operate as a standalone device or may be connected (e.g., networked) to other machines. In a networked deployment, machine 800 may operate in the capacity of a server machine, a client machine, or both in server-client network environments. In an example, machine 800 may act as a peer machine in peer-to-peer (P2P) (or other distributed) network environment. Machine 800 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 800 can include one or more devices having structures with transistors as discussed with respect to IC 400 of FIG. 4.

Machine (e.g., computer system) 800 may include a hardware processor 850 (e.g., a CPU, a GPU, a hardware processor core, or any combination thereof), a main memory 855 and a static memory 856, some or all of which may communicate with each other via an interlink (e.g., bus) 858. Machine 800 may further include a display device 860, an alphanumeric input device 862 (e.g., a keyboard), and a user interface (UI) navigation device 864 (e.g., a mouse). In an example, display device 860, alphanumeric input device 862, and UI navigation device 864 may be a touch screen display. Machine 800 may additionally include a mass storage (e.g., drive unit) 851, a signal generation device 868 (e.g., a speaker), a network interface device 857, and one or more sensors 866, such as a global positioning system (GPS) sensor, compass, accelerometer, or other sensor. Machine 800 may include an output controller 869, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 800 may include a machine-readable medium on which is stored one or more sets of data structures or instructions 854 (for example, software or microcode) embodying or utilized by machine 800. Instructions 854 may also reside, completely or at least partially, within main memory 855, within static memory 856, within mass storage 851, or within hardware processor 850 during execution thereof by machine 800. In an example, one or any combination of hardware processor 850, main memory 855, static memory 856, or mass storage 851 may constitute machine-readable medium. Machine-readable medium can be a single medium or multiple media (e.g., a centralized or distributed database, or associated caches and servers) configured to store one or more instructions 854.

The term “machine-readable medium” may include any medium that is capable of storing instructions for execution by machine 800 and that cause machine 800 to perform any one or more of the techniques for which machine 800 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include RAM, DRAM, SRAM, or SDRAM.

Instructions 854 (e.g., software, programs, microcode, an operating system (OS), etc.) or other data stored on mass storage 851, can be accessed by main memory 855 for use by processor 850. Main memory 855 (e.g., DRAM) is typically fast, but volatile, and thus a different type of storage than mass storage 851 (e.g., an SSD), which is suitable for long-term storage, including while in an “off” condition. Instructions 854 or data in use by a user or machine 800 are typically loaded in main memory 855 for use by processor 850. When main memory 855 is full, virtual space from mass storage 851 can be allocated to supplement main memory 855; however, because mass storage 851 is typically slower than main memory 855, and write speeds are typically at least twice as slow as read speeds, use of virtual memory can greatly reduce user experience due to storage device latency (in contrast to main memory 855, e.g., DRAM). Further, use of mass storage 851 for virtual memory can greatly reduce the usable lifespan of mass storage 851.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 854 may further be transmitted or received over a network 859 using a transmission medium via network interface device 857 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 857 may include one or more physical jacks (e.g., Ethernet, coaxial, or phone jacks) or one or more antennas to connect to the communications network 859. In an example, network interface device 857 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 800 or data to or from machine 800. The transportation can include using digital or analog communications signals that can be transmitted over the transmission medium to facilitate communication of such software or data.

The following are example embodiments of devices and methods, in accordance with the teachings herein.

An example integrated circuit 1 can comprise a set of complementary metal oxide semiconductor (CMOS) devices, where the set includes two CMOS devices having transistors with low threshold voltages and a third CMOS device having transistors with high threshold voltages. The third CMOS device can be situated between and adjacent the two CMOS devices. The transistors of the third CMOS device can have gate extensions that extend from gates of the transistors beyond source and drain diffusion regions of the transistors of the third CMOS device such that the high threshold voltages are shifted above the low threshold voltages due to the gate extensions.

An example integrated circuit 2 can include features of example integrated circuit 1 and can include n-type transistors of the two CMOS devices and a n-type transistor of the third CMOS device having a common implant level and p-type transistors of the two CMOS devices and a p-type transistor of the third CMOS device having a common implant level.

An example integrated circuit 3 can include features of any of the preceding example integrated circuits and can include contacts to gates of n-type transistors of the two CMOS devices being located substantially at edges of source and drain diffusion regions of the n-type transistors of the two CMOS devices and a contact to the gate of a n-type transistor of the third CMOS device being located substantially at an end of the gate extension, opposite edges of the source and drain diffusion regions of the n-type transistor of the third CMOS device.

An example integrated circuit 4 can include features of example integrated circuit 3 and any of the preceding example integrated circuits and can include contacts to gates of p-type transistors of the two CMOS devices being located substantially at edges of source and drain diffusion regions of the p-type transistors and a contact to the gate of a p-type transistor of the third CMOS device being located substantially at an end of the gate extension opposite edges of the source and drain diffusion regions of the p-type transistor of the third CMOS device.

An example integrated circuit 5 can include features of example integrated circuit 4 and any of the preceding example integrated circuits and can include the contacts to gates of the n-type transistors of the two CMOS devices and the contact to the gate of the n-type transistor of the third CMOS device being colinear, and the contacts to gates of the p-type transistors of the two CMOS devices and the contact to the gate of the p-type transistor of the third CMOS device being colinear.

An example integrated circuit 6 can include features of any of the preceding example integrated circuits and can include gates of the transistors of the two CMOS devices and the gates of the transistors of the third CMOS to include high-k metal gates.

An example integrated circuit 7 can include features of any of the preceding example integrated circuits and can include the gates of the transistors of the third CMOS to include polysilicon that is part of the gate extensions.

An example integrated circuit 8 can include features of any of the preceding example integrated circuits and can include the integrated circuit being a dynamic random-access memory and the set of CMOS devices being structured in a periphery to a memory array of the dynamic random-access memory.

In an example integrated circuit 9, any of the integrated circuits of example integrated circuits 1 to 8 may be incorporated into an electronic apparatus further comprising a host processor or memory controller and a communication bus extending between the host processor/memory controller and the integrated circuit.

In an example integrated circuit 10, any of the integrated circuits of example integrated circuits 1 to 9 may be modified to include any structure presented in another of example integrated circuit 1 to 9.

In an example integrated circuit 11, any apparatus associated with the integrated circuits of example integrated circuits 1 to 10 may further include a machine-readable storage device configured to store instructions as a physical state, wherein the instructions may be used to perform one or more operations of the apparatus.

In an example integrated circuit 12, any of the integrated circuits of example integrated circuits 1 to 11 may be formed or operated in accordance with any of the below example methods 1 to 11.

An example integrated circuit 13 can comprise a set of complementary metal oxide semiconductor (CMOS) devices, where each CMOS device of the set is directly adjacent another CMOS of the set. The set can include a first family of CMOS devices of the set and a second family of CMOS devices of the set. Each transistor of the first family can have a low threshold voltage and each transistor of the second family can have a high threshold voltage. One or more CMOS devices of the second family can be mixed with CMOS devices of the first family such that transistors of the one or more CMOS devices of the second family have implant levels substantially equal to implant levels of the CMOS devices of the first family.

An example integrated circuit 14 can include features of example integrated circuit 13 and can include the high threshold voltages of the transistors of the one or more CMOS devices being based on gate extensions that extend from gates of the transistors of the one or more CMOS devices substantially beyond source and drain diffusion regions of the transistors of the one or more CMOS devices.

An example integrated circuit 15 can include features of example integrated circuit 13 and example integrated circuit 14 and can include the gate extensions to include polysilicon.

An example integrated circuit 16 can include features of any of the preceding example integrated circuits 13 to 15 and can include the transistors of the first family and the second family to include high-k metal gates.

An example integrated circuit 17 can include features of any of the preceding example integrated circuits 13 to 16 and can include the integrated circuit being a memory device and the set of CMOS devices being structured in a periphery to a memory array of the memory device, with the first family arranged to support high speed circuitry in the periphery and the second family arranged to provide low speed support functions.

In an example integrated circuit 18, any of the integrated circuits of example integrated circuits 13 to 17 may be incorporated into an electronic apparatus further comprising a host processor or memory controller and a communication bus extending between the host processor/memory controller and the integrated circuit.

In an example integrated circuit 19, any of the integrated circuits of example integrated circuits 13 to 18 may be modified to include any structure presented in another of example integrated circuit 13 to 18.

In an example integrated circuit 20, any apparatus associated with the integrated circuits of example integrated circuits 13 to 19 may further include a machine-readable storage device configured to store instructions as a physical state, wherein the instructions may be used to perform one or more operations of the apparatus.

In an example integrated circuit 21, any of the integrated circuits of example integrated circuits 13 to 20 may be formed or operated in accordance with any of the below example methods 1 to 11 of forming an integrated circuit.

An example method 1 of forming an integrated circuit can comprise forming two CMOS devices with transistors having low threshold voltages and forming a third CMOS device. Threshold voltages of transistors of the third CMOS device are tuned, structuring the transistors of the third CMOS device to have high threshold voltages shifted above the low threshold voltages of the transistors of the two CMOS. The threshold voltages can be tuned by forming gate extensions that extend from gates of the transistors of the third CMOS device substantially beyond source and drain diffusion regions of the transistors of the third CMOS device.

An example method 2 can include features of example method 1 and can include forming the third CMOS structured between and directly adjacent the two CMOS devices.

An example method 3 can include features of any of the preceding example methods and can include forming n-type transistors of the two CMOS devices and a n-type transistor of the third CMOS device to have a common implant level; and forming p-type transistors of the two CMOS devices and a p-type transistor of the third CMOS device to have a common implant level.

An example method 4 can include features of any of the preceding example methods and can include: forming contacts to gates of n-type transistors of the two CMOS devices substantially at edges of source and drain diffusion regions of the n-type transistors of the two CMOS devices; forming a contact to the gate of a n-type transistor of the third CMOS device substantially at an end of the gate extension, opposite edges of the source and drain diffusion regions of the n-type transistor of the third CMOS device; forming contacts to gates of p-type transistors of the two CMOS devices substantially at edges of source and drain diffusion regions of the p-type transistors; and forming a contact to the gate of a p-type transistor of the third CMOS device substantially at an end of the gate extension, opposite edges of the source and drain diffusion regions of the p-type transistor of the third CMOS device.

An example method 5 can include features of example method 4 and any of the preceding example methods and can include forming the contacts to the gates of the n-type transistors of the two CMOS devices colinear with the contact to the gate of the n-type transistor of the third CMOS device; and forming the contacts to the gates of the p-type transistors of the two CMOS devices colinear with the contact to the gate of the p-type transistor of the third CMOS device.

An example method 6 can include features of any of the preceding example methods and can include forming the transistors of the two CMOS devices and the transistors of the third CMOS device to include forming high-k metal gates; and forming gate extensions includes forming polysilicon as at least part of the gate extensions.

An example method 7 can include features of any of the preceding example methods and can include forming the integrated circuit as a memory die and forming a set of CMOS devices structured in a periphery to a memory array of the memory die and structured as a first family of CMOS devices of the set, each transistor of the first family having a low threshold voltage and a second family of CMOS devices of the set, each transistor of the second family having a high threshold voltage.

In an example method 8, any of the example methods 1 to 7 may be performed in operating a memory device further comprising a host processor and a communication bus extending between the host processor and a memory device.

In an example method 9, any of the example methods 1 to 8 may be modified to include operations set forth in any other of example methods 1 to 4.

In an example method 10, any of the example methods 1 to 9 may be implemented at least in part through use of instructions stored as a physical state in one or more machine-readable storage devices.

An example method 11 can include features of any of the preceding example methods 1 to 10 and can include performing functions associated with any features of example integrated circuits 1 to 25.

An example machine-readable storage device storing instructions, that when executed by one or more processors, cause a machine to perform operations, can comprise instructions to perform functions associated with any features of example integrated circuits 1 to 21 or perform methods associated with any features of example methods 1 to 11.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. An integrated circuit comprising:
a set of complementary metal oxide semiconductor (CMOS) devices, the set including:
two CMOS devices having transistors with low threshold voltages; and
a third CMOS device having transistors with high threshold voltages, the third CMOS device between and adjacent the two CMOS devices, the transistors of the third CMOS device having gate extensions that extend from gates of the transistors beyond source and drain diffusion regions of the transistors of the third CMOS device such that the high threshold voltages are shifted above the low threshold voltages due to the gate extensions.

2. The integrated circuit of claim 1, wherein n-type transistors of the two CMOS devices and a n-type transistor of the third CMOS device have a common implant level and p-type transistors of the two CMOS devices and a p-type transistor of the third CMOS device have a common implant level.

3. The integrated circuit of claim 1, wherein contacts to gates of n-type transistors of the two CMOS devices are located substantially at edges of source and drain diffusion regions of the n-type transistors of the two CMOS devices and a contact to the gate of a n-type transistor of the third CMOS device is located substantially at an end of the gate extension, opposite edges of the source and drain diffusion regions of the n-type transistor of the third CMOS device.

4. The integrated circuit of claim 3, wherein contacts to gates of p-type transistors of the two CMOS devices are located substantially at edges of source and drain diffusion regions of the p-type transistors and a contact to the gate of a p-type transistor of the third CMOS device is located substantially at an end of the gate extension opposite edges of the source and drain diffusion regions of the p-type transistor of the third CMOS device.

5. The integrated circuit of claim 4, wherein the contacts to gates of the n-type transistors of the two CMOS devices and the contact to the gate of the n-type transistor of the third CMOS device are colinear, and the contacts to gates of the p-type transistors of the two CMOS devices and the contact to the gate of the p-type transistor of the third CMOS device are colinear.

6. The integrated circuit of claim 1, wherein gates of the transistors of the two CMOS devices and the gates of the transistors of the third CMOS include high-k metal gates.

7. The integrated circuit of claim 1, wherein the gates of the transistors of the third CMOS include polysilicon that is part of the gate extensions.

8. The integrated circuit of claim 1, wherein the integrated circuit is a dynamic random-access memory and the set of CMOS devices are structured in a periphery to a memory array of the dynamic random-access memory.

9. An integrated circuit comprising:
a set of complementary metal oxide semiconductor (CMOS) devices, each CMOS device of the set directly adjacent another CMOS of the set, the set including:
a first family of CMOS devices of the set, each transistor of the first family having a low threshold voltage; and
a second family of CMOS devices of the set, each transistor of the second family having a high threshold voltage, one or more CMOS devices of the second family mixed with CMOS devices of the first family such that transistors of the one or more CMOS devices of the second family have implant levels substantially equal to implant levels of the CMOS devices of the first family.

10. The integrated circuit of claim 9, wherein the high threshold voltages of the transistors of the one or more CMOS devices are based on gate extensions that extend from gates of the transistors of the one or more CMOS devices substantially beyond source and drain diffusion regions of the transistors of the one or more CMOS devices.

11. The integrated circuit of claim 10, wherein the gate extensions include polysilicon.

12. The integrated circuit of claim 9, wherein the transistors of the first family and the second family include high-k metal gates.

13. The integrated circuit of claim 9, wherein the integrated circuit is a memory device and the set of CMOS devices are structured in a periphery to a memory array of the memory device, with the first family arranged to support high speed circuitry in the periphery and the second family arranged to provide low speed support functions.

14. A method of forming an integrated circuit, the method comprising:
forming two complementary metal oxide semiconductor (CMOS) devices with transistors having low threshold voltages;
forming a third CMOS device; and
tuning threshold voltages of transistors of the third CMOS device, structuring the transistors of the third CMOS device to have high threshold voltages shifted above the low threshold voltages of the transistors of the two CMOS, by forming gate extensions that extend from gates of the transistors of the third CMOS device substantially beyond source and drain diffusion regions of the transistors of the third CMOS device.

15. The method of claim 14, wherein the method includes forming the third CMOS structured between and directly adjacent the two CMOS devices.

16. The method of claim 14, wherein the method includes:
forming n-type transistors of the two CMOS devices and a n-type transistor of the third CMOS device having a common implant level; and
forming p-type transistors of the two CMOS devices and a p-type transistor of the third CMOS device having a common implant level.

17. The method of claim 14, wherein the method includes:
forming contacts to gates of n-type transistors of the two CMOS devices substantially at edges of source and drain diffusion regions of the n-type transistors of the two CMOS devices;
forming a contact to the gate of a n-type transistor of the third CMOS device substantially at an end of the gate extension, opposite edges of the source and drain diffusion regions of the n-type transistor of the third CMOS device;
forming contacts to gates of p-type transistors of the two CMOS devices substantially at edges of source and drain diffusion regions of the p-type transistors; and
forming a contact to the gate of a p-type transistor of the third CMOS device substantially at an end of the gate extension, opposite edges of the source and drain diffusion regions of the p-type transistor of the third CMOS device.

18. The method of claim 17, wherein the method includes:
forming the contacts to the gates of the n-type transistors of the two CMOS devices colinear with the contact to the gate of the n-type transistor of the third CMOS device; and
forming the contacts to the gates of the p-type transistors of the two CMOS devices colinear with the contact to the gate of the p-type transistor of the third CMOS device.

19. The method of claim 14, wherein forming the transistors of the two CMOS devices and the transistors of the third CMOS device includes forming high-k metal gates; and forming gate extensions includes forming polysilicon as at least part of the gate extensions.

20. The method of claim 14, wherein the method includes forming the integrated circuit as a memory die and forming a set of CMOS devices structured in a periphery to a memory array of the memory die and structured as a first family of CMOS devices of the set, each transistor of the first family having a low threshold voltage and a second family of CMOS devices of the set, each transistor of the second family having a high threshold voltage.
